(19) United States
(12) Patent Application Publication
(10) Pub. No.: US 2018/0037982 A1
(43) Pub. Date: Feb. 8, 2018

(54) LINEAR EVAPORATION SOURCE AND DEPOSITION APPARATUS INCLUDING THE SAME

(71) Applicant: Samsung Display Co., Ltd., Yongin-si (KR)

(72) Inventors: Byounggu AN, Asan-si (KR); Jinho OH, Yangsan-si (KR); Changsun YOON, Cheonan-si (KR); Mincheol CHA, Pyeongtaek-si (KR); Eugene KANG, Suwon-si (KR)

(21) Appl. No.: 15/660,450

(22) Filed: Jul. 26, 2017

(30) Foreign Application Priority Data
Aug. 5, 2016 (KR) 10-2016-0099964

(51) Int. Cl. C23C 14/24; C23C 14/50

(52) U.S. Cl. CPC C23C 14/243; C23C 14/50

(57) ABSTRACT

A linear evaporation source includes: a crucible accommodating an evaporation material; a heating unit enclosing the crucible and heating the crucible; and a nozzle unit above the crucible, the nozzle unit including a nozzle plate and at least one nozzle protruding from the nozzle plate. A length of the crucible is about 5 times to about 30 times greater than a width of the crucible. The crucible includes molybdenum (Mo) in an amount of about 95.0 percentage by weight (wt %) to about 99.99 wt % and lanthanum oxide (La₂O₃) in an amount of about 0.01 wt % to about 5 wt %, with respect to the total weight of the crucible.

### CROSS-REFERENCE TO RELATED APPLICATION

This application claims the priority to and all the benefits accruing under 35 U.S.C. §119 of Korean Patent Application No. 10-2016-0099964, filed on Aug. 5, 2016, with the Korean Intellectual Property Office (“KIPO”), the disclosure of which is incorporated herein in its entirety by reference.

### BACKGROUND

### 1. Field

Embodiments of the present inventive concept relate to a linear evaporation source and to a deposition apparatus including the linear evaporation source, and more particularly, to a linear evaporation source including a crucible that includes a molybdenum-lanthanum alloy and to a deposition apparatus including the linear evaporation source.

### 2. Description of the Related Art

Examples of methods for forming a thin film on a substrate may include a physical vapor deposition (“PVD”) method, such as vacuum evaporation, ion plating, and sputtering, and a chemical vapor deposition (“CVD”) method using gas reaction.

A deposition apparatus for performing vacuum evaporation typically includes an evaporation source that includes a crucible for accommodating an evaporation material, a heater for heating the crucible, and a nozzle through which the evaporation material is released.

An example of the evaporation source may include a linear evaporation source having a shape elongated in a direction. The linear evaporation source is suitable for forming a deposition layer on a large-sized substrate. However, since having an elongated shape, the linear evaporation source may be fragile to be easily broken at a high temperature, have a temperature deviation based on position, and exhibit low thermal stability.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Aspects of embodiments of the present inventive concept are directed to a linear evaporation source having high thermal stability.

Further, aspects of embodiments of the present inventive concept are directed to a linear evaporation source that may be used in metal deposition and a deposition apparatus including the linear evaporation source.

According to an exemplary embodiment of the present inventive concept, a linear evaporation source includes: a crucible configured to accommodate an evaporation material; a heating unit enclosing the crucible and configured to heat the crucible; and a nozzle unit above the crucible, the nozzle unit including a nozzle plate and at least one nozzle protruding from the nozzle plate. A length of the crucible is about 5 times to about 30 times greater than a width of the crucible. The crucible includes molybdenum (Mo) in an amount of about 95.0 percentage by weight (wt %) to about 99.99 wt % and lanthanum oxide (La₂O₃) in an amount of about 0.01 wt % to about 5 wt %, with respect to the total weight of the crucible.

The crucible may include molybdenum (Mo) in an amount of about 99.5 wt % to about 99.9 wt % and lanthanum oxide (La₂O₃) in an amount of about 0.1 wt % to about 0.5 wt %, with respect to the total weight of the crucible.

The crucible may have a length ranging from about 50 cm to about 500 cm, a width ranging from about 5 cm to about 30 cm, and a height ranging from about 10 cm to about 60 cm.

The crucible may be formed by molding, sintering, and forging a mixture of a molybdenum (Mo) powder in an amount of about 95.0 wt % to about 99.99 wt % and a lanthanum oxide (La₂O₃) powder in an amount of about 0.01 wt % to about 5 wt %, with respect to the total weight of the crucible.

The linear evaporation source may further include at least one partition wall along a length direction of the crucible.

The crucible may have at least one slit defined in a side wall along the length direction of the crucible, and the partition wall may be detachably inserted into the slit.

The partition wall may be spaced apart from a bottom surface of the crucible.

The heating unit may be configured to heat the crucible to a temperature ranging from about 1000° C. to about 2000° C.

The heating unit may include a heater frame and a heater on the heater frame, and the heater may include a plurality of heating elements along a length direction of the heater frame.

The plurality of heating elements may be spaced apart from one another along the length direction of the heater frame.

A density of the plurality of heating elements at an upper portion of the heater frame may be higher than a density of the plurality of heating elements at a lower portion of the heater frame.

The plurality of heating elements may include an upper heating element at an upper portion of the heater frame and a lower heating element below the upper heating element.

The linear evaporation source may further include a radiant heat shielding plate. The radiant heat shielding plate may have an aperture for inserting the at least one nozzle and cover the nozzle unit.

The radiant heat shielding plate may include at least one selected from the group consisting of: manganese (Mn), titanium (Ti), ZrO₂, Al₂O₃, TiO₂, pyrolytic boron nitride (PBN), aluminium nitride (AlN), and steel use stainless (SUS).

The linear evaporation source may further include a heat conductive plate between the nozzle plate of the nozzle unit and the radiant heat shielding plate. The heat conductive plate may have a hole corresponding to the at least one nozzle and have thermal conductivity.

The linear evaporation source may further include an inner plate between a bottom surface of the crucible and the nozzle unit, the inner plate having a plurality of holes.

The linear evaporation source may further include a protection container between the crucible and the hating unit.

The protection container may include at least one selcted from the group consisting of: tantalum (Ta), pyrolytic boron nitride (PBN), steel use stainless (SUS), aluminium nitride (AlN), molybdenum (Mo) and a molybdenum-lanthanum (Mo—La) alloy.

According to an exemplary embodiment of the present inventive concept, a deposition apparatus includes: a process chamber; a linear evaporation source in the process chamber; and a substrate holder spaced apart from the linear evaporation source. The linear evaporation source includes: a crucible configured to accommodate an evaporation material; a heating unit enclosing the crucible and configured to heat the crucible; and a nozzle unit above the crucible, the nozzle unit including a nozzle plate and at least one nozzle protruding from the nozzle plate. A length of the crucible is about 5 times to about 30 times greater than a width of the crucible. The crucible includes molybdenum (Mo) in an amount of about 95.0 wt % to about 99.99 wt % and lanthanum oxide (La₂O₃) in an amount of about 0.01 wt % to about 5 wt %, with respect to the total weight of the crucible.

The crucible may include molybdenum (Mo) in an amount of about 99.5 wt % to about 99.9 wt % and lanthanum oxide (La₂O₃) in an amount of about 0.1 wt % to about 0.5 wt % with respect to the total weight of the crucible.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present disclosure of invention will be more clearly understood from the following detailed description taken in conjunction with the accompanying drawings, in which:

FIG. 1 is a cross-sectional view illustrating a deposition apparatus according to a first exemplary embodiment;

FIG. 2 is an exploded perspective view illustrating a linear evaporation source according to a second exemplary embodiment;

FIG. 3 is a perspective view illustrating the linear evaporation source according to the second exemplary embodiment;

FIG. 4 is a cross-sectional view taken along line I-I′ of FIG. 3;

FIG. 5 is a cross-sectional view taken along line II-IP of FIG. 3;

FIG. 6 is a partial perspective view illustrating a state in which a crucible is disposed in a heating unit;

FIG. 7A is a perspective view illustrating a crucible according to a third exemplary embodiment, and FIG. 7B is a cross-sectional view along a length direction of the crucible taken along line of FIG. 7A;

FIG. 8A a cross-sectional view along a length direction of a crucible according to a fourth exemplary embodiment, and FIG. 8B is a cross-sectional view along a width direction of the crucible according to the fourth exemplary embodiment;

FIG. 9A is a plan view illustrating a partition wall according to a fifth exemplary embodiment, and FIG. 9B is a cross-sectional view illustrating disposition of the partition wall according to the fifth exemplary embodiment;

FIG. 10 is a perspective view illustrating a heating unit according to an exemplary embodiment;

FIG. 11 is a cross-sectional view along a length direction of a heating unit according to an alternative exemplary embodiment;

FIG. 12 is a cross-sectional view along a length direction of a heating unit according to another alternative exemplary embodiment;

FIG. 13 is a cross-sectional view along a length direction of a heating unit according to still another alternative exemplary embodiment;

FIG. 14 is a cross-sectional view along a length direction of a heating unit according to yet another alternative exemplary embodiment; and

FIG. 15 is an exploded perspective view illustrating a linear evaporation source according to a sixth exemplary embodiment.

### DETAILED DESCRIPTION

Exemplary embodiments will now be described more fully hereinafter with reference to the accompanying drawings. Although the invention can be modified in various manners and have several embodiments, exemplary embodiments are illustrated in the accompanying drawings and will be mainly described in the specification. However, the scope of the invention is not limited to the exemplary embodiments and should be construed as including all the changes, equivalents, and substitutions included in the spirit and scope of the invention.

In the drawings, thicknesses of a plurality of layers and areas are illustrated in an enlarged manner for clarity and ease of description thereof. When a layer, area, or plate is referred to as being “on” another layer, area, or plate, it may be directly on the other layer, area, or plate, or intervening layers, areas, or plates may be present therebetween. Conversely, when a layer, area, or plate is referred to as being “directly on” another layer, area, or plate, intervening layers, areas, or plates may be absent therebetween. Further when a layer, area, or plate is referred to as being “below” another layer, area, or plate, it may be directly below the other layer, area, or plate, or intervening layers, areas, or plates may be present therebetween. Conversely, when a layer, area, or plate is referred to as being “directly below” another layer, area, or plate, intervening layers, areas, or plates may be absent therebetween.

The spatially relative terms “below”, “beneath”, “less”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Some of the parts which are not associated with the description may not be provided to specifically describe embodiments of the present inventive concept, and like reference numerals refer to like elements throughout the specification.

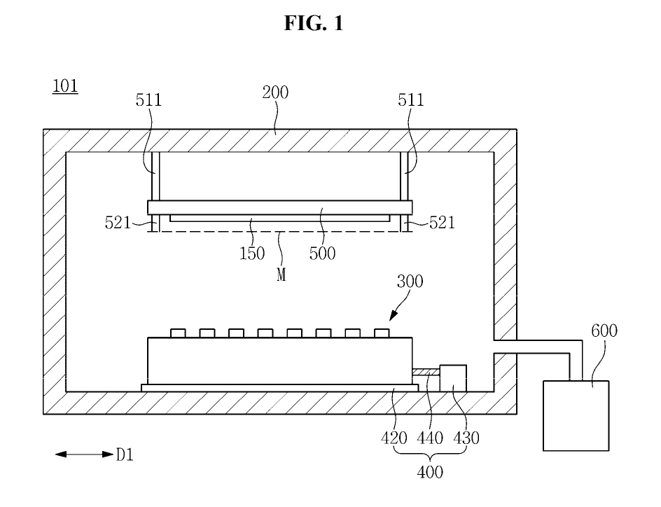

Hereinafter, a first exemplary embodiment will be described with reference to FIG. 1.

FIG. 1 is a cross-sectional view illustrating a deposition apparatus 101 according to the first exemplary embodiment.

Referring to FIG. 1, the deposition apparatus 101 according to the first exemplary embodiment includes a process chamber 200, a linear evaporation source 300 in the process chamber 200, and a substrate holder 500 opposing the linear evaporation source 300.

The process chamber 200 serves to provide a space for performing a deposition process and control a pressure inside the process chamber 200. The process chamber 200 is connected to a vacuum pump 600 for exhausting an evaporation material that is not deposited on a substrate 150.

In addition, the process chamber 200 may include an inlet (not illustrated) through which the substrate 150 to be subject to deposition may be drawn in or out.

The substrate holder 500 is configured to allow the substrate 150 that is drawn inside the process chamber 200 to be seated thereon, and may include a fastening member for fastening the substrate 150 during a deposition process. The substrate holder 500 may be fixed to the process chamber 200 by a fixing means 511.

In a deposition process, in order for an evaporation material to be deposited on the substrate 150 into a predetermined pattern, a mask M is disposed between the linear evaporation source 300 and the substrate holder 500. The mask M may be defined with a plurality of slits. The substrate holder 500 may include a mask supporting member 521.

It is illustrated in FIG. 1 that the linear evaporation source 300 is disposed at a lower portion of the process chamber 200, the substrate holder 500 is disposed at an upper portion of the process chamber 200, and the substrate 150 is fastened by the substrate holder 500 to be horizontal with respect to the ground, but the first exemplary embodiment is not limited thereto.

For example, the linear evaporation source 300 may be disposed on one side surface of the process chamber 200, the substrate holder 500 may be disposed on another side surface of the process chamber 200, and the substrate 150 fastened to the substrate holder 500 may have an angle ranging from about 70 degrees (°) to about 110° with respect to the ground. In such an exemplary embodiment, sagging of the substrate 150 due to gravity may be effectively reduced by the angle with of substrate 150 with respect to the ground.

The linear evaporation source 300 accommodates an evaporation material, heats the evaporation material, and sprays the heated evaporation material onto the substrate 150 such that the evaporation material forms a layer on the substrate 150. The linear evaporation source 300 extends (e.g., is elongated) in a first direction D1. Referring to FIG. 1, the first direction D1 corresponds to a transverse direction of the drawing.

The deposition apparatus 101 may further include an evaporation source transfer unit 400. The evaporation source transfer unit 400 serves to transfer the linear evaporation source 300 in the first direction D1 or in a direction intersecting the first direction D1. The evaporation source transfer unit 400 may include a ball screw 440, a motor 430 turning the ball screw 440, and a guide 420 for controlling a transfer direction of the linear evaporation source 300, for example.

Hereinafter, a linear evaporation source and configurations of the linear evaporation source will be described in detail.

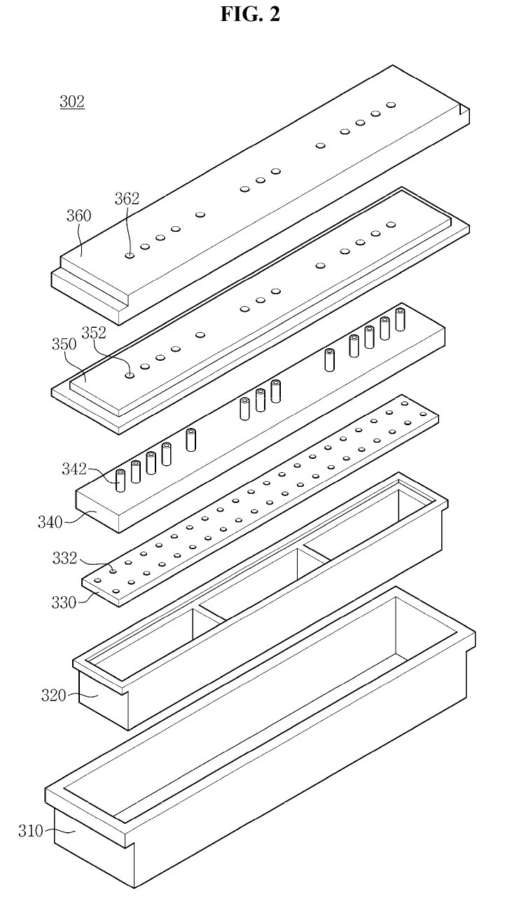

Hereinafter, a second exemplary embodiment will be described with reference to FIGS. 2, 3, 4, 5, and 6.

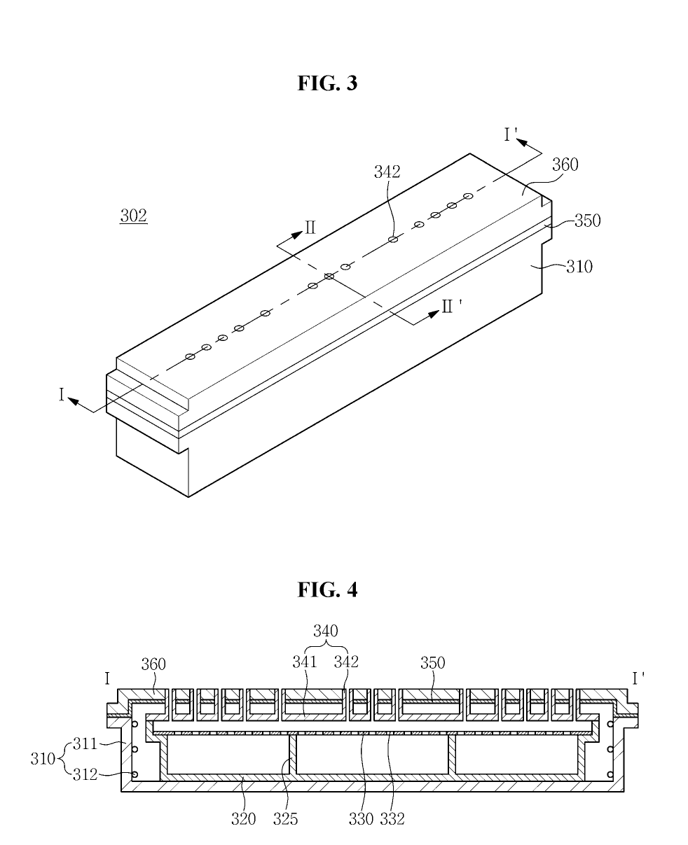

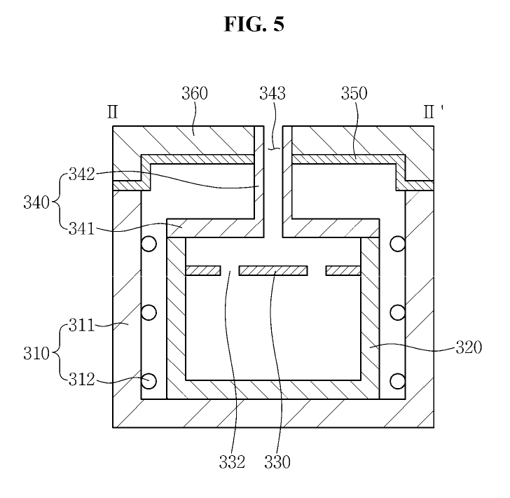

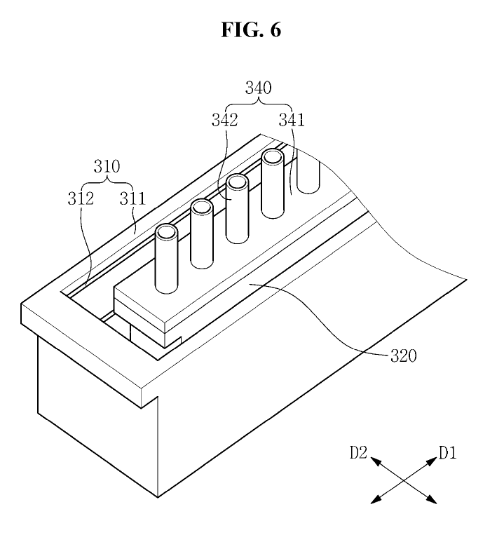

FIG. 2 is an exploded perspective view illustrating a linear evaporation source 302 according to the second exemplary embodiment, FIG. 3 is a perspective view illustrating the linear evaporation source 302 according to the second exemplary embodiment, FIG. 4 is a cross-sectional view taken along line I-I′ of FIG. 3, FIG. 5 is a cross-sectional view taken along line II-II′ of FIG. 3, and FIG. 6 is a partial perspective view illustrating a state in which a crucible 320 is disposed in a heating unit 310.

Referring to FIGS. 2, 3, 4, 5, and 6, the linear evaporation source 302 according to the second exemplary embodiment includes the heating unit 310, the crucible 320, an inner plate 330, a nozzle unit 340, a heat conductive plate 350, and a radiant heat shielding plate 360. Although not illustrated, the linear evaporation source 302 may further include a temperature sensing unit.

The crucible 320 is configured to accommodate an evaporation material, and an upper portion of the crucible 320 is exposed. The evaporation material refers to a material forming a layer by deposition and is also referred to as an evaporation source.

The crucible 320 extends (e.g., is elongated) in a first direction D1. That is, the crucible 320 has a linear shape.

A length of the crucible 320 may be about five times to about thirty times greater than a width thereof. In an exemplary embodiment, the crucible 320 may have a length ranging from about 50 cm to about 500 cm, a width ranging from about 5 cm to about 30 cm, and a height ranging from about 10 cm to about 60 cm. For example, the crucible 320 may have a length ranging from about 50 cm to about 200 cm, a width ranging from about 10 cm to about 20 cm, and a height ranging from about 20 cm to about 30 cm. However, the second exemplary embodiment is not limited thereto, and a size of the crucible 320 may vary as necessary. Referring to FIG. 6, the first direction D1 corresponds to a length direction of the crucible 320, a second direction D2 corresponds to a width direction of the crucible 320, and a direction orthogonal to the first direction D1 and the second direction D2, i.e., an up-and-down direction in the drawing, corresponds to a height direction of the crucible 320.

The linear evaporation source 302 including the crucible 320 having such a linear shape is advantageous over a point evaporation source that has a bowl shape or a boat shape, when forming a deposition layer on a large-sized substrate.

In order to deposit a material, e.g., a metal material, which is evaporated at a high temperature of about 1000° C. or more, a crucible having high-temperature stability is needed. Due to an issue of the high-temperature stability, a point evaporation source has been conventionally used for high temperature deposition performed at a high temperature of about 1000° C. or more.

The point evaporation source has a relatively small size, and thus has a relatively low temperature deviation within the point evaporation source and has excellent thermal stability. However, there is a limit in a deposition range, i.e., a deposition area, which is covered by a single point evaporation source. Thus, a plurality of point evaporation sources are required to form a deposition layer on a large-sized substrate. However, in such an exemplary embodiment, there is a difficulty in achieving a uniform deposition layer due to a deposition deviation.

The crucible 320 according to the second exemplary embodiment includes an alloy of molybdenum (Mo) and lanthanum (La) (or lanthanum oxide (La₂O₃)), thus having excellent high-temperature stability, and thus is advantageous when used in high-temperature deposition using a material that is evaporated at a temperature of about 1000° C. or more. In addition, although having a linear shape, the crucible 320 may not be broken or worn down at a high temperature. Accordingly, the crucible 320 according to the second exemplary embodiment may be suitable to the linear evaporation source 302 used at a high temperature.

The linear evaporation source 302 according to the second exemplary embodiment that includes such a crucible 320 may be suitable to a deposition process using a metal material and to a process of forming a deposition layer on a large-sized substrate.

According to the second exemplary embodiment, the crucible 320 includes an alloy of molybdenum (Mo) and lanthanum (La) (or lanthanum oxide (La₂O₃)). In consideration of thermal stability, mechanical characteristics, and molding properties of the crucible 320, a content of lanthanum (La) or lanthanum oxide (La₂O₃) is adjusted. For example, the crucible 320 may include molybdenum (Mo) in an amount of about 95.0 percentage by weight (wt %) to about 99.99 wt % and lanthanum oxide (La₂O₃) in an amount of about 0.01 wt % to about 5 wt %, with respect to the total weight of the crucible 320. In a case where a content of lanthanum oxide (La₂O₃) is less than about 0.01 wt % or more than about 5 wt %, thermal stability, mechanical characteristics, and molding properties of the crucible 320 may be degraded.

In an exemplary embodiment, the crucible 320 may include molybdenum (Mo) in an amount of about 98.0 wt % to about 99.99 wt % and lanthanum oxide (La₂O₃) in an amount of about 0.01 wt % to about 2 wt %, with respect to the total weight of the crucible 320. For example, the crucible 320 may include molybdenum (Mo) in an amount of about 99.5 wt % to about 99.9 wt % and lanthanum oxide (La₂O₃) in an amount of about 0.1 wt % to about 0.5 wt %, with respect to the total weight of the crucible 320.

For example, the crucible 320 may include molybdenum (Mo) in an amount of about 99.5 wt % and lanthanum oxide (La₂O₃) in an amount of about 0.5 wt %. An alloy including molybdenum (Mo) and lanthanum oxide (La₂O₃) may have a structure in which lanthanum oxide (La₂O₃) is positioned in an interstitial site of a BCC crystalline structure of molybdenum (Mo).

The crucible 320 may be formed through molding and sintering using a powder mixture of molybdenum (Mo) and lanthanum (La) or a powder mixture of molybdenum (Mo) and lanthanum oxide (La₂O₃). In addition, after sintering, a thermal treatment process or a forging process may further be performed.

Sintering may be performed at a temperature ranging from about 2000° C. to about 2500° C. For example, sintering may be performed at a temperature of about 2200° C.

Thermal treatment or forging may be performed at a temperature ranging from about 1300° C. to about 1500° C. For example, forging may be performed at a temperature of about 1400° C. Thermal stability of the crucible 320 may be improved through forging or thermal treatment.

The linear evaporation source 302 may include at least one partition wall 325 disposed in the crucible 320. The partition wall 325 serves to partition the evaporation material accommodated in the crucible 320 and prevent the evaporation material from being unnecessarily concentrated on one side. Accordingly, heat applied from the heating unit 310 may be transmitted to the evaporation material uniformly. The partition wall 325 is not invariably necessary and may be omitted.

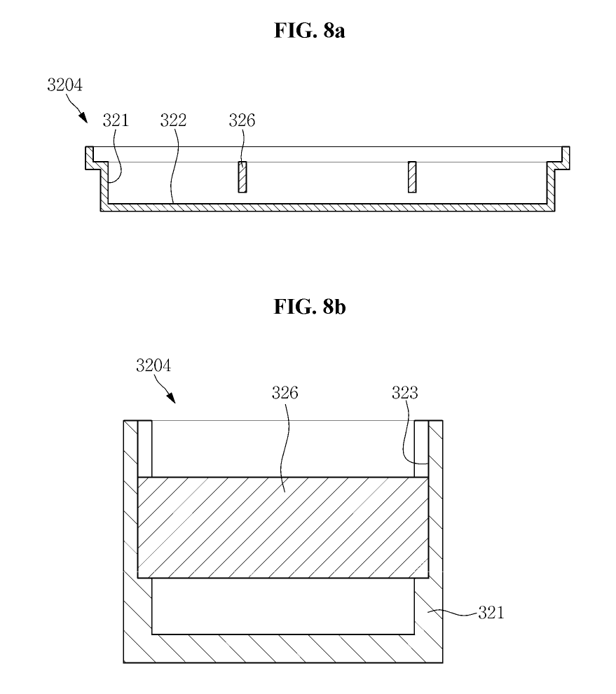

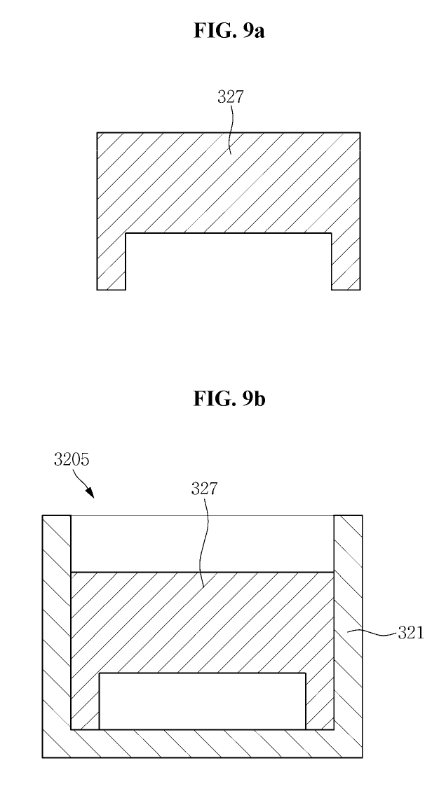

The partition wall 325 may include a passage (refer to FIGS. 8B and 9B) through which the evaporation material may move. The evaporation material moves through such a passage, and thus an amount of the evaporation material that is accommodated in each area defined by the partition wall 325 may be uniformly adjusted.

The partition wall 325 may include substantially a same material as a material included in the crucible 320. For example, the partition wall 325 may include molybdenum (Mo) in an amount of about 95.0 wt % to about 99.99 wt % and lanthanum oxide (La₂O₃) in an amount of about 0.01 wt % to about 5 wt %, with respect to the total weight of the partition wall 325. In consideration of thermal stability, mechanical characteristics, and molding properties of the partition wall 325, a content of lanthanum (La) or lanthanum oxide (La₂O₃) is adjusted. In a case where a content of lanthanum oxide (La₂O₃) is less than about 0.01 wt % or more than about 5 wt %, thermal stability, mechanical characteristics, and molding properties of the partition wall 325 may be degraded.

For example, the partition wall 325 may include molybdenum (Mo) in an amount of about 98.0 wt % to about 99.99 wt % and lanthanum oxide (La₂O₃) in an amount of about 0.01 wt % to about 2 wt %, with respect to the total weight of the partition wall 325.

The nozzle unit 340 includes a nozzle plate 341 above the exposed upper portion of the crucible 320 and at least one nozzle 342 protruding from the nozzle plate 341.

Referring to FIGS. 1 and 4, the nozzle unit 340 includes a plurality of nozzles 342. The plurality of nozzles 342 may be disposed along the first direction D1 at equidistant gaps, or may not. For example, referring to FIGS. 2 and 4, the plurality of nozzles 342 are disposed along the first direction D1 at non-equidistant gaps. In order to impart a uniform thickness to a layer that is formed by deposition, gaps among the nozzles 342 may be adjusted. The gap among the nozzles 342 may vary based on the kinds of the evaporation material, a heating temperature of the crucible 320, a size of the crucible 320, and a size of a substrate to be subject to deposition.

The nozzle 342 has a hole 343 passing through the nozzle plate 341, and the evaporation material in the crucible 320 is dispersed through the nozzle 342 outwardly of the linear evaporation source 302 and then deposited on the substrate 150 subject to deposition.

The heating unit 310 is configured to heat the crucible 320. The heating unit 310 includes a heater frame 311 and a heater 312 fixed to the heater frame 311.

The heater frame 311 is spaced apart from the crucible 320 to enclose a side surface and a bottom surface, and not an upper surface, of the crucible 320. A shape of the heater frame 311 is not particularly limited, as long as the heater frame 311 may support the heater 312.

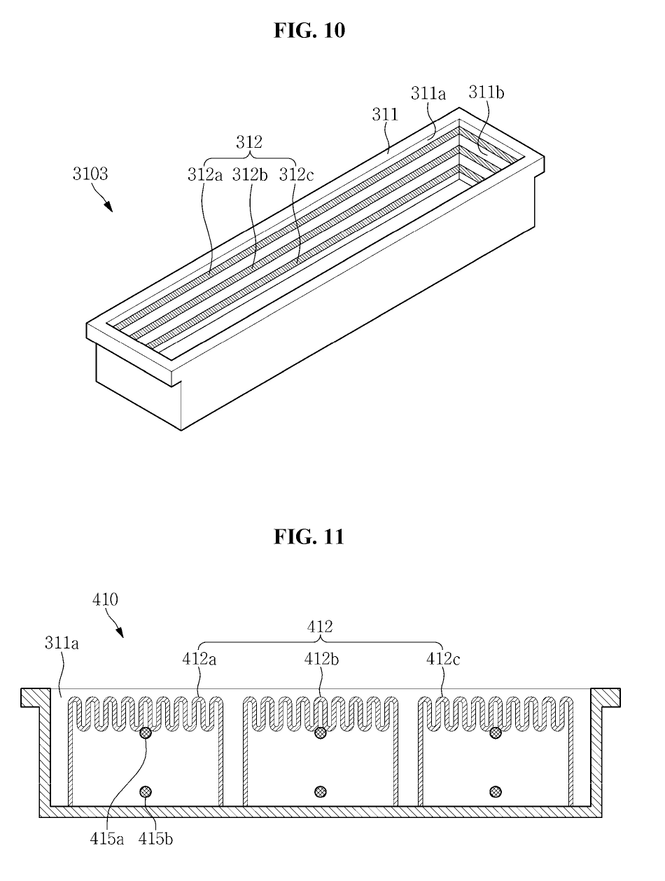

In some embodiments of the present inventive concept, the heater 312 is disposed on an inner wall 311a and 311b (as shown in an example in FIG. 10) facing the crucible 320. The heater 312 may include a heating coil, and may heat the side surface and the bottom surface of the crucible 320 to control a temperature of the crucible 320 uniformly.

The heating unit 310 may heat the crucible 320 so that the temperature of the crucible 320 becomes about 1000° C. to about 2000° C.

The heating unit 310 may include a single heater or may include a plurality of separated heaters. Referring to FIGS. 4, 5, and 6, the heater 312 including a plurality of heating elements is disposed on the heater frame 311. In FIG. 6, a direction D1 corresponds to a length direction of the heater frame 311. The heater 312 is disposed at least on a side wall of the heater frame 311 along the length direction.

FIG. 6 illustrates the heater 312 including a plurality of heating elements disposed along the inner wall of the heater frame 311. However, the second exemplary embodiment is not limited thereto, and a plurality of separate plate-shaped or circular-shaped heaters may be disposed on the inner wall of the heater frame 311. In addition, a temperature of each heater 312 may be adjusted, separately.

The position and the number of the heaters 312 may vary as necessary. In a case where the crucible 320 is heated to a relatively high temperature, a great number of heaters 312 may be used. In an exemplary embodiment, in a case where the crucible 320 is heated to a high temperature, e. g., about 1500° C. or more, in order to prevent agglomeration of the evaporation material at the nozzle unit 340, the heaters 312 may be largely disposed adjacent to an upper portion of the crucible 320. Where necessary, the heaters 312 may be largely disposed adjacent to a lower portion of the crucible 320.

The linear evaporation source 302 may include a temperature sensing unit (not illustrated). The temperature sensing unit, for example, may be fixed to the heater frame 311 to be disposed between the crucible 320 and the heater 312.

The position and the number of the temperature sensing units may vary based on sizes of the crucible 320 and the heater 312. For example, the temperature sensing unit may measure the temperature of the crucible 320 for each position thereof. Based on the temperature of the crucible 320 for each position which is measured by the temperature sensing unit, the temperature of the heater 312 is controlled such that an overall temperature of the crucible 320 may be uniformly controlled.

The radiant heat shielding plate 360 has an aperture 362 for inserting the nozzle 342, and covers the nozzle unit 340.

The radiant heat shielding plate 360 may be disposed above the heating unit 310 to enclose the crucible 320 and the nozzle unit 340. The radiant heat shielding plate 360 serves to suppress release of heat generated from the heating unit 310 to inside of the process chamber 200. Accordingly, heat emitted from the crucible 320 and the heating unit 310, having a high temperature, may not affect a deposition layer or may not damage a structure inside the chamber.

The nozzle 342 is inserted into the aperture 362 of the radiant heat shielding plate 360. An end portion of the nozzle 342 is exposed by the aperture 362. The nozzle 342 may protrude from the aperture 362 or may not. For example, referring to FIG. 4, the nozzle 342 has substantially a same height as a height of an upper surface of the radiant heat shielding plate 360, and so does not protrude from the aperture 362. The nozzle 342 may be disposed to be dented from the upper surface of the radiant heat shielding plate 360.

The radiant heat shielding plate 360 may include a material having a relatively low heat transfer coefficient and relatively low emissivity. For example, the radiant heat shielding plate 360 may include at least one of: manganese (Mn), titanium (Ti), ZrO₂, Al₂O₃, TiO₂, pyrolytic boron nitride (PBN), aluminum nitride (AlN), and steel use stainless (SUS).

The heat conductive plate 350 is disposed between the nozzle plate 341 of the nozzle unit 340 and the radiant heat shielding plate 360. The heat conductive plate 350 has thermal conductivity, and has a hole 352 corresponding to the nozzle 342.

The nozzle 342 is inserted into the hole 352 of the heat conductive plate 350.

The heat conductive plate 350 may include a heat conductive material. The heat conductive plate 350 may include tantalum (Ta), for example. In an alternative exemplary embodiment, the heat conductive plate 350 may include a metal alloy such as aluminum alloys and molybdenum alloys.

The heat conductive plate 350 may be spaced apart from the radiant heat shielding plate 360 or may contact the radiant heat shielding plate 360.

In addition, the heat conductive plate 350 may be adjacent to the nozzle 342 or may contact the nozzle 342. As heat is transmitted through the heat conductive plate 350, the nozzles 342 may have a substantially uniform temperature. That is, the heat conductive plate 350 may prevent heat from being concentrated to one of the nozzles 342, and thus may serve to reduce a temperature deviation among the nozzles 342. Accordingly, materials evaporated from the crucible 320 are uniformly dispersed within the process chamber 200 through the nozzle 342.

As disposed above the crucible 320, the heat conductive plate 350 is also referred to as an upper plate.

The inner plate 330 is disposed in the crucible 320. For example, the inner plate 330 is disposed between a bottom surface 322 of the crucible 320 and the nozzle unit 340, and has a plurality of holes 332.

The inner plate 330 may serve as a filter. For example, the inner plate 330 serves to allow the material evaporated in the crucible 320 to be uniformly dispersed and flow into the nozzle 342.

The inner plate 330 may include substantially a same material as a material included in the crucible 320. For example, the inner plate 330 may include molybdenum (Mo) in an amount of about 95.0 wt % to about 99.99 wt % and lanthanum oxide (La₂O₃) in an amount of about 0.01 wt % to about 5 wt %, with respect to the total weight of the inner plate 330. In consideration of thermal stability, mechanical characteristics, and molding properties of the inner plate 330, a content of lanthanum (La) or lanthanum oxide (La₂O₃) is adjusted. In a case where a content of lanthanum oxide (La₂O₃) is less than about 0.01 wt % or more than about 5 wt %, thermal stability, mechanical characteristics, and molding properties of the inner plate 330 may be degraded.

For example, the inner plate 330 may include molybdenum (Mo) in an amount of about 98.0 wt % to about 99.99 wt % and lanthanum oxide (La₂O₃) in an amount of about 0.01 wt % to about 2 wt %, with respect to the total weight of the inner plate 330.

The inner plate 330 may be disposed at a locking projection formed at the crucible 320. The crucible 320 may further include a separate holder (not illustrated) for the inner plate 330.

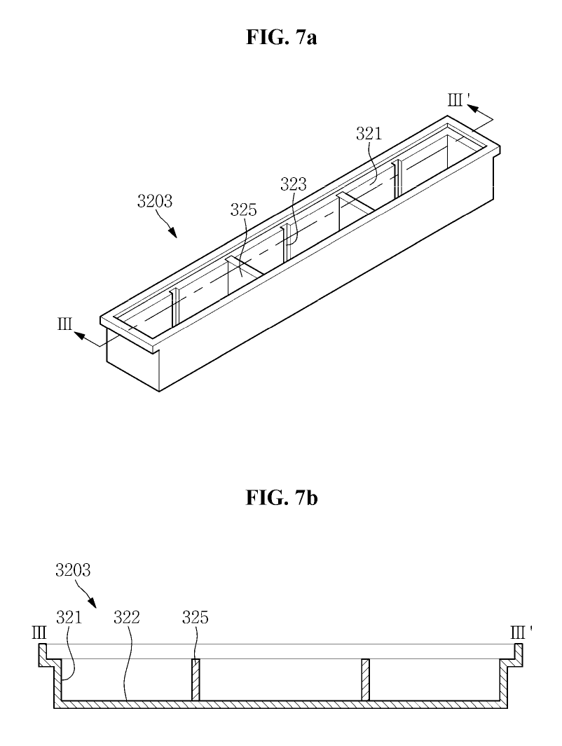

Hereinafter, a third exemplary embodiment will be described with reference to FIGS. 7A and 7B.

FIG. 7A is a perspective view illustrating a crucible 3203 according to the third exemplary embodiment, and FIG. 7B is a cross-sectional view along a length direction of the crucible 3203 taken along line of FIG. 7A.

Referring to FIG. 7A, the crucible 3203 has at least one slit 323 defined in a side wall 321 along a length direction D1. A partition wall 325 may be detachably inserted into the slit 323.

The position and the number of the slits 323 may vary as necessary. The number of the partition walls 325 may also vary as necessary. Accordingly, an inner space of the crucible 3203 may be divided as necessary, using the partition wall 325.

Hereinafter, a fourth exemplary embodiment will be described with reference to FIGS. 8A and 8B.

FIG. 8A a cross-sectional view along a length direction of a crucible 3204 according to the fourth exemplary embodiment, and FIG. 8B is a cross-sectional view along a width direction of the crucible 3204 according to the fourth exemplary embodiment.

Referring to FIGS. 8A and 8B, a partition wall 326 is spaced apart from a bottom surface 322 of the crucible 3204. Referring to FIG. 8B, a slit 323 is defined in a side wall 321 of the crucible 3204, and the slit 323 is defined only at an upper portion of the side wall 321, and does not extend to the bottom surface 322 of the crucible 3204. Accordingly, although the partition wall 326 is inserted into the slit 323, the partition wall 326 may not contact the bottom surface 322 of the crucible 3204 such that a space is secured between the bottom surface 322 of the crucible 3204 and the partition wall 326.

The space between the bottom surface 322 of the crucible 3204 and the partition wall 326 becomes a passage for an evaporation material accommodated in the crucible 3204. A melted evaporation material may move through the space between the bottom surface 322 of the crucible 3204 and the partition wall 326. Accordingly, an amount of the evaporation material accommodated in each area defined by the partition wall 326 may become substantially uniform.

Hereinafter, a fifth exemplary embodiment will be described with reference to FIGS. 9A and 9B.

FIG. 9A is a plan view illustrating a partition wall 327 according to the fifth exemplary embodiment, and FIG. 9B is a cross-sectional view illustrating a crucible 3205 including the partition wall 327 according to the fifth exemplary embodiment.

Referring to FIG. 9, the partition wall 327 has an inverted U-like shape. In a case where such a partition wall 327 is provided in the crucible 3205, a space may be secured between the partition wall 327 and a bottom surface 322 of the crucible 3205. An evaporation material may readily move through the space between the bottom surface 322 of the crucible 3205 and the partition wall 327.

FIG. 10 is a perspective view illustrating a heating unit 3103 according to an exemplary embodiment.

Referring to FIG. 10, a heater 312 including a plurality of heating elements 312a, 312b, and 312c is disposed on an inner wall 311a and 311b of a heater frame 311. The kinds of the heating elements 312a, 312b, and 312c are not particularly limited. An example of the heating elements may include a heating coil. Any heating means known in the pertinent art other than the heating coil may be used as the heating elements 312a, 312b, and 312c.

A long side of the heater frame 311 is referred to as a length direction, and a short side of the heater frame 311 is referred to as a width direction. The length direction corresponds to the direction D1 of FIG. 6, and the width direction corresponds to the direction D2 of FIG. 6. In FIG. 10, each of the heating elements 312a, 312b, and 312c is continuously disposed along an inner wall 311a along the length direction and an inner wall 311b along the width direction.

FIG. 11 is a cross-sectional view along a length direction of a heating unit 410 according to an alternative exemplary embodiment.

In the heating unit 410 illustrated in FIG. 11, a heater 412 includes a plurality of heating elements 412a, 412b, and 412c disposed on an inner wall 311a of a heater frame 311 along a length direction. The heating elements 412a, 412b, and 412c may use a heating coil.

Referring to FIG. 11, the heating elements 412a, 412b, and 412c are densely disposed at an upper portion of the heater frame 311 that is adjacent to a nozzle unit 340. That is, a density of the heating elements 412a, 412b, and 412c is higher at the upper portion of the heater frame 311 than a density of the heating elements 412a, 412b, and 412c at a lower portion of the heater frame 311.

For example, the heater 412 includes three heating elements 412a, 412b, and 412c, and each of the heating elements 412a, 412b, and 412c may have an inverted U-like shape (∩).

The heater 412, illustrated in FIG. 11, having such a shape may readily heat the upper portion of the crucible 320.

In addition, the heating unit 410 illustrated in FIG. 11 includes a temperature sensing unit 415a and 415b. The temperature sensing unit 415a and 415b measures temperature. Based on the temperature measured by the temperature sensing unit 415a and 415b, a temperature of the heating elements 412a, 412b, and 412c may be adjusted. The temperature sensing unit 415a and 415b includes an upper temperature sensing unit 415a adjacent to the heating elements 412a, 412b, and 412c and a lower temperature sensing units 415b spaced apart from the heating elements 412a, 412b, and 412c.

The upper temperature sensing unit 415a may directly measure the temperature of the heating elements 412a, 412b, and 412c. The lower temperature sensing unit 415b may measure a temperature of an area spaced apart from the heating elements 412a, 412b, and 412c at a relatively great distance, thus detecting whether a temperature of the heating unit 410 falls below a predetermined temperature.

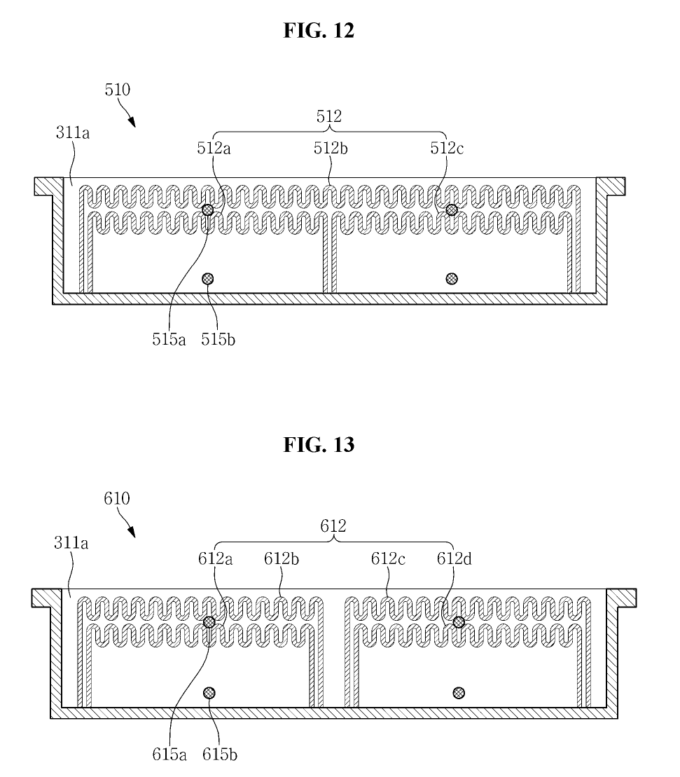

FIG. 12 is a cross-sectional view along a length direction of a heating unit 510 according to another alternative exemplary embodiment.

The heating unit 510 illustrated in FIG. 12 includes a plurality of heating elements 512a, 512b, and 512c disposed on an inner wall 311a of a heater frame 311 along a length direction.

Referring to FIG. 12, a heater 512 includes an upper heating element 512b at an upper portion of the heater frame 311 that is adjacent to a nozzle unit 340 and two lower heating elements 512a and 512c below the upper heating element 512b. In such an exemplary embodiment, each of the heating elements 512a, 512b, and 512c has an inverted U-like shape (∩).

Referring to FIG. 12, the heating elements 512a, 512b, and 512c are densely disposed at an upper portion of the heater frame 311. That is, a density of the heating elements 512a, 512b, and 512c is higher at the upper portion of the heater frame 311 than a density of the heating elements 512a, 512b, and 512c at a lower portion of the heater frame 311. The heater 512 having such a shape may readily heat the upper portion of the crucible 320.

In addition, the heating unit 510 illustrated in FIG. 12 includes a temperature sensing unit 515a and 515b. The temperature sensing unit 515a and 515b includes an upper temperature sensing unit 515a adjacent to the heating elements 512a, 512b, and 512c and a lower temperature sensing unit 515b spaced apart from the heating elements 512a, 512b, and 512c.

FIG. 13 is a cross-sectional view along a length direction of a heating unit 610 according to still another alternative exemplary embodiment;

The heating unit 610 illustrated in FIG. 13 includes a plurality of heating elements 612a, 612b, 612c, and 612d disposed on an inner wall 311a of a heater frame 311 along a length direction.

Referring to FIG. 13, a heater 612 includes two upper heating elements 612b and 612c at an upper portion of the heater frame 311 that is adjacent to a nozzle unit 340 and two lower heating elements 612a and 612d below respective ones of the two upper heating elements 612b and 612c. In such an exemplary embodiment, each of the heating elements 612a, 612b, 612c and 612d has an inverted U-like shape (∩).

Referring to FIG. 13, the heating elements 612a, 612b, 612c and 612d are densely disposed at an upper portion of the heater frame 311 that is adjacent to the nozzle unit 340. The heater 612 having such a shape may readily heat the upper portion of the crucible 320.

In addition, the heating unit 610 illustrated in FIG. 13 includes a temperature sensing unit 615a and 615b. The temperature sensing unit 615a and 615b includes an upper temperature sensing unit 615a adjacent to the heating elements 612a, 612b, 612c and 612d and a lower temperature sensing unit 615b spaced apart from the heating elements 612a, 612b, 612c and 612d.

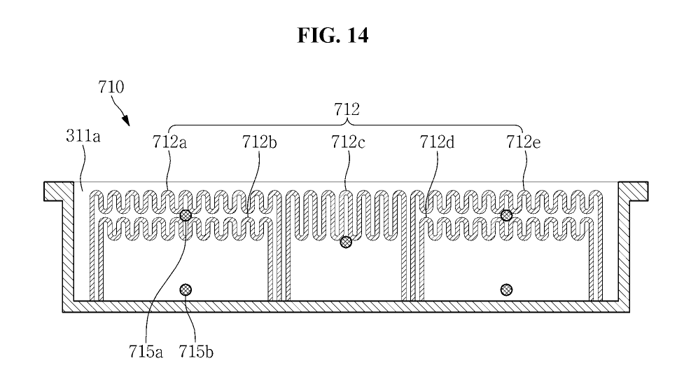

FIG. 14 is a cross-sectional view along a length direction of a heating unit 710 according to yet another alternative exemplary embodiment.

The heating unit 710 illustrated in FIG. 14 includes a plurality of heating elements 712a, 712b, 712c, 712d, and 712e disposed on an inner wall 311a of a heater frame 311 along a length direction.

Referring to FIG. 14, a heater 712 includes side heating elements 712a, 712b, 712d, and 712e respectively disposed on left and right sides of the inner wall 311a of the heater frame 311 along the length direction, and a central heating element 712c disposed among the side heating elements 712a, 712b, 712d, and 712e. The side heating elements 712a, 712b, 712d, and 712e include two upper heating elements 712a and 712e at an upper portion of the heater frame 311 that is adjacent to the nozzle unit 340 and two lower heating elements 712b and 712d below respective ones of the two upper heating elements 712a and 712e. In such an exemplary embodiment, each of the heating elements 712a, 712b, 712c, 712d, and 712e has an inverted U-like shape (∩).

Referring to FIG. 14, the heating elements 712a, 712b, 712c, 712d, and 712e are densely disposed at an upper portion of the heater frame 311 that is adjacent to the nozzle unit 340. The heater 712 having such a shape may readily heat the upper portion of the crucible 320.

In addition, the heating unit 710 illustrated in FIG. 14 includes a temperature sensing unit 715a and 715b. The temperature sensing unit 715a and 715b includes an upper temperature sensing unit 715a adjacent to the heating elements 712a, 712b, 712c, 712d, and 712e and a lower temperature sensing unit 715b spaced apart from the heating elements 712a, 712b, 712c, 712d, and 712e.

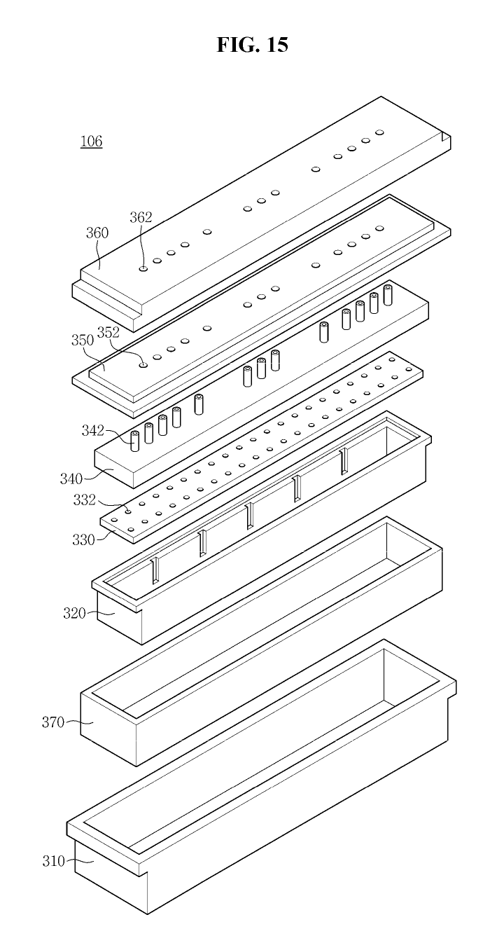

Hereinafter, a sixth exemplary embodiment will be described with reference to FIG. 15.

FIG. 15 is an exploded perspective view illustrating a linear evaporation source 106 according to a sixth exemplary embodiment.

As compared to the linear evaporation source 302 according to the second exemplary embodiment, the linear evaporation source 106 according to the sixth exemplary embodiment further includes a protection container 370 between a crucible 320 and a heating unit 310. Hereinafter, to avoid repetition, descriptions pertaining to configurations described hereinabove will be omitted.

The protection container 370 illustrated in FIG. 15 has a space for accommodating the crucible 320. The protection container 370 accommodates and protects the crucible 320, thus allowing the crucible 320 to be heated uniformly. As disposed outside of the crucible 320, the protection container 370 may also be referred to as an external crucible.

The protection container 370 may include substantially a same material as or a different material from a material included in the crucible 320. The protection container 370 may include tantalum (Ta), pyrolytic boron nitride (PBN), steel use stainless (SUS), aluminium nitride (AlN), molybdenum (Mo), and/or a molybdenum-lanthanum (Mo—La) alloy, for example.

For example, the protection container 370 may include molybdenum (Mo) in an amount of about 95.0 wt % to about 99.99 wt % and lanthanum oxide (La₂O₃) in an amount of about 0.001 wt % to about 5 wt %, with respect to the total weight of the protection container 370. In consideration of thermal stability, mechanical characteristics, and molding properties of the protection container 370, a content of lanthanum (La) or lanthanum oxide (La₂O₃) is adjusted. In a case where a content of lanthanum oxide (La₂O₃) is less than about 0.01 wt % or more than about 5 wt %, thermal stability, mechanical characteristics, and molding properties of the protection container 370 may be degraded.

For example, the protection container 370 may include molybdenum (Mo) in an amount of about 98.0 wt % to about 99.99 wt % and lanthanum oxide (La₂O₃) in an amount of about 0.001 wt % to about 2 wt %, with respect to the total weight of the protection container 370.

In addition, referring to FIG. 15, a partition wall is not provided in the crucible 320. However, the sixth exemplary embodiment is not limited thereto, and the partition wall may be provided in the crucible 320.

As set forth hereinabove, a crucible according to one or more exemplary embodiments has high thermal stability and excellent durability, and thus a process risk whereby the crucible may be broken in a deposition process may be effectively reduced. Further, a linear evaporation source according to one or more exemplary embodiments has high thermal stability and may accommodate a greater amount of evaporation materials, as compared to a conventional point evaporation source. Accordingly, a continuous driving time of a deposition apparatus increases such that a process efficiency is improved and a manufacturing cost may be reduced

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Various features of the above described and other embodiments can be mixed and matched in any manner, to produce further embodiments consistent with the invention.

What is claimed is:

1. A linear evaporation source comprising:
a crucible configured to accommodate an evaporation material;
a heating unit enclosing the crucible and configured to heat the crucible; and
a nozzle unit above the crucible, the nozzle unit comprising a nozzle plate and at least one nozzle protruding from the nozzle plate,
wherein a length of the crucible is about 5 times to about 30 times greater than a width of the crucible, and
the crucible comprises molybdenum (Mo) in an amount of about 95.0 percentage by weight (wt %) to about 99.99 wt % and lanthanum oxide (La₂O₃) in an amount of about 0.01 wt % to about 5 wt %, with respect to the total weight of the crucible.

2. The linear evaporation source as claimed in claim 1, wherein the crucible comprises molybdenum (Mo) in an amount of about 99.5 wt % to about 99.9 wt % and lanthanum oxide (La₂O₃) in an amount of about 0.1 wt % to about 0.5 wt %, with respect to the total weight of the crucible.

3. The linear evaporation source as claimed in claim 1, wherein the crucible has a length ranging from about 50 cm to about 500 cm, a width ranging from about 5 cm to about 30 cm, and a height ranging from about 10 cm to about 60 cm.

4. The linear evaporation source as claimed in claim 1, wherein the crucible is formed by molding, sintering, and forging a mixture of a molybdenum (Mo) powder in an amount of about 95.0 wt % to about 99.99 wt % and a lanthanum oxide (La₂O₃) powder in an amount of about 0.01 wt % to about 5 wt %, with respect to the total weight of the crucible.

5. The linear evaporation source as claimed in claim 1, further comprising at least one partition wall along a length direction of the crucible.

6. The linear evaporation source as claimed in claim 5, wherein the crucible has at least one slit defined in a side wall along the length direction of the crucible, and
the partition wall is detachably inserted into the slit.

7. The linear evaporation source as claimed in claim 5, wherein the partition wall is spaced apart from a bottom surface of the crucible.

8. The linear evaporation source as claimed in claim 1, wherein the heating unit is configured to heat the crucible to a temperature ranging from about 1000° C. to about 2000° C.

9. The linear evaporation source as claimed in claim 1, wherein the heating unit comprises a heater frame and a heater on the heater frame, and
the heater comprises a plurality of heating elements along a length direction of the heater frame.

10. The linear evaporation source as claimed in claim 9, wherein the plurality of heating elements are spaced apart from one another along the length direction of the heater frame.

11. The linear evaporation source as claimed in claim 10, wherein a density of the plurality of heating elements at an upper portion of the heater frame is higher than a density of the plurality of heating elements at a lower portion of the heater frame.

12. The linear evaporation source as claimed in claim 10, wherein the plurality of heating elements comprise an upper heating element at an upper portion of the heater frame and a lower heating element below the upper heating element.

13. The linear evaporation source as claimed in claim 1, further comprising a radiant heat shielding plate, wherein the radiant heat shielding plate has an aperture for inserting the at least one nozzle and covers the nozzle unit.

14. The linear evaporation source as claimed in claim 9, wherein the radiant heat shielding plate comprises at least one selected from the group consisting of: manganese (Mn), titanium (Ti), ZrO₂, Al₂O₃, TiO₂, pyrolytic boron nitride (PBN), aluminium nitride (AlN), and steel use stainless (SUS).

15. The linear evaporation source as claimed in claim 9, further comprising a heat conductive plate between the nozzle plate of the nozzle unit and the radiant heat shielding plate, wherein the heat conductive plate has a hole corresponding to the at least one nozzle and has thermal conductivity.

16. The linear evaporation source as claimed in claim 1, further comprising an inner plate between a bottom surface of the crucible and the nozzle unit, the inner plate having a plurality of holes.

17. The linear evaporation source as claimed in claim 1, further comprising a protection container between the crucible and the heating unit.

18. The linear evaporation source as claimed in claim 17, wherein the protection container comprises at least one selected from the group consisting of: tantalum (Ta), pyrolytic boron nitride (PBN), steel use stainless (SUS), aluminium nitride (AlN), molybdenum (Mo) and a molybdenum-lanthanum (Mo—La) alloy.

19. A deposition apparatus comprising:
a process chamber;
a linear evaporation source in the process chamber; and
a substrate holder spaced apart from the linear evaporation source,
wherein the linear evaporation source comprises:
a crucible configured to accommodate an evaporation material;
a heating unit enclosing the crucible and configured to heat the crucible; and
a nozzle unit above the crucible, the nozzle unit comprising a nozzle plate and at least one nozzle protruding from the nozzle plate,
a length of the crucible is about 5 times to about 30 times greater than a width of the crucible, and
the crucible comprises molybdenum (Mo) in an amount of about 95.0 wt % to about 99.99 wt % and lanthanum oxide (La₂O₃) in an amount of about 0.01 wt % to about 5 wt %, with respect to the total weight of the crucible.

20. The deposition apparatus as claimed in claim 19, wherein the crucible comprises molybdenum (Mo) in an amount of about 99.5 wt % to about 99.9 wt % and lanthanum oxide (La₂O₃) in an amount of about 0.1 wt % to about 0.5 wt % with respect to the total weight of the crucible.
